(19) United States
(12) Patent Application Publication
(10) Pub. No.: US 2019/0347165 A1
(43) Pub. Date: Nov. 14, 2019

(54) APPARATUS AND METHOD FOR RECOVERING DISTRIBUTED FILE SYSTEM

(71) Applicant: ELECTRONICS AND TELECOMMUNICATIONS RESEARCH INSTITUTE, Daejeon (KR)

(72) Inventor: Dong-Oh KIM, Daejeon (KR)

(21) Appl. No.: 16/206,701

(22) Filed: Nov. 30, 2018

(30) Foreign Application Priority Data
May 8, 2018 (KR) 10-2018-0052649

(51) Int. Cl. G06F 11/14; G06F 16/182; G06F 16/11; H03M 13/47

(52) U.S. Cl. CPC G06F 11/1461; G06F 11/1448; H03M 13/47; G06F 16/122; G06F 16/182

(57) ABSTRACT

Disclosed herein are an apparatus and method for recovering a distributed file system. The method, in which the apparatus for recovering a distributed file system is used, includes detecting a failed file that needs recovery, among files stored in a distributed file system; performing recovery scheduling in order to set a recovery order based on which parallel recovery is to be performed for the failed file; and performing parallel recovery for the failed file based on the recovery scheduling.

### CROSS REFERENCE TO RELATED APPLICATION

This application claims the benefit of Korean Patent Application No. 10-2018-0052649, filed May 8, 2018, which is hereby incorporated by reference in its entirety into this application.

### BACKGROUND OF THE INVENTION

### 1. Technical Field

The present invention relates generally to Erasure Coding (EC) and data recovery technology, and more particularly to parallel data recovery in a distributed file system using EC.

### 2. Description of the Related Art

With an increase in the scale of storage, various methods for reducing storage-related costs have received a lot of attention. Particularly, as the space efficiency of storage becomes more important, technology related to Erasure Coding (EC) has received a lot of attention.

Methods for improving the fault tolerance of data in storage may be largely categorized into replication and EC. Replication is a method in which data loss is prevented by maintaining multiple copies of data, and EC is a method in which data loss is prevented by breaking data into multiple fragments and generating multiple parity fragments. EC is specified in a ‘K+M EC’ format, which indicates that data is broken into K data fragments, and M parity fragments are generated for the K data fragments through computation.

Replication may reduce space efficiency because multiple copies of a file are stored. EC may provide better space efficiency than replication because parity is used, and may improve fault tolerance by increasing the number parity fragments. For example, both triple replication and ‘8+2 EC’ may tolerate up to two failures, but the space efficiency of EC is 80%, which is three times higher than that of replication, which is 33%.

Also, although double replication and ‘2+2 EC’ have the same space efficiency of 50%, double replication may tolerate only one failure, but EC may tolerate two failures. Therefore, EC has better space efficiency and better fault tolerance than replication.

However, in the case of EC, data is broken into multiple fragments so as to be stored across multiple storage devices, whereby the data access speed may be decreased. Furthermore, because a single file is split into multiple files and stored across multiple storage devices (each file stored in the storage device being called a ‘chunk’), there is a high probability of performing recovery of a file when a failure occurs in any one of the storage devices. But the number of storage devices used for data input/output when recovery is performed is greater than when replication is used. For example, in the case of triple replication, because three identical chunks are distributed, access to only one storage device is required when data is read. However, in the case ‘8+2 EC’, ten chunks are distributed, and access to at least eight storage devices is required when data is read.

Due to such characteristics of EC, when input/output and recovery are performed, it is likely that a bottleneck will occur in accessed resources or that a recovery load will be imposed on a certain node. Particularly, when EC supports parallel recovery, it is difficult to balance recovery load on nodes, and a bottleneck between resources occurs. Here, performance degradation arising from a bottleneck may result in overall recovery performance degradation.

Meanwhile, Korean Patent Application Publication No. 10-2012-0032920, titled “System and method for distributed processing of file volume in units of chunks” discloses a system and method for generating chunks by partitioning a file volume, storing the generated chunks so as to be distributed, and computing the same.

However, Korean Patent Application Publication No. 10-2012-0032920 has a limitation in that the performance of storage (resources) is degraded due to a bottleneck between resources when a file is recovered in a distributed file system.

### SUMMARY OF THE INVENTION

An object of the present invention is to efficiently perform data recovery in a distributed file system in which erasure coding is used.

Another object of the present invention is to minimize resource contention that is caused when parallel recovery is performed in a distributed file system in which erasure coding is used.

A further object of the present invention is to minimize resource contention in a distributed file system in which erasure coding is used and to thereby construct high-capacity cloud storage having dramatically improved recovery speed.

In order to accomplish the above objects, a method for recovering a distributed file system, in which an apparatus for recovering a distributed file system is used, according to an embodiment of the present invention includes detecting a failed file that needs recovery, among files stored in a distributed file system; performing recovery scheduling in order to set a recovery order based on which parallel recovery is to be performed for the failed file; and performing parallel recovery for the failed file based on the recovery scheduling.

Here, the distributed file system may store a file in units of chunks that are distributed across multiple storage devices using an Erasure Coding (EC) technique.

Here, detecting the failed file may configured to detect the failed file depending on preset conditions and to register the failed file in a failed file list when the failed file is determined to be recoverable, and performing the recovery scheduling may be configured to perform the recovery scheduling for the failed file according to the order of registration in the failed file list.

Here, performing the recovery scheduling may be configured to determine whether storage devices to which access is required for recovery of the failed file are available among the multiple storage devices.

Here, the storage devices to which access is required may include a storage device including a chunk from which data necessary for recovery of the failed file is to be read and a storage device including a chunk to which recovered data is to be written.

Here, performing the recovery scheduling may be configured to determine whether the storage devices to which access is required are available depending on whether the storage devices to which access is required are capable of accepting input/output requests.

Here, performing the recovery scheduling may be configured such that, when it is determined that all of the storage devices to which access is required are available, the failed file is registered in any one of a priority recovery list and a general recovery list depending on whether it is necessary to recover the failed file first.

Here, performing the recovery scheduling may be configured such that, when it is determined that at least one of the storage devices to which access is required is unavailable, the failed file is again registered in the failed file list.

Here, performing the recovery scheduling may be configured to check the failed file that is registered again or to perform scheduling in response to a request form a recovery worker.

Here, performing parallel recovery may be configured to perform parallel recovery by recovering data from chunks in storage devices in which the failed file is stored and by writing recovered data to storage devices including chunks for writing the recovered data.

Here, performing parallel recovery may be configured to check the performing parallel recovery, to analyze the layout of a recovered file, and to control registration of use of the storage devices that were used to perform parallel recovery.

Also, in order to accomplish the above objects, an apparatus for recovering a distributed file system according to an embodiment of the present invention includes a metadata management unit for detecting a failed file that needs recovery, among files stored in a distributed file system, and performing recovery scheduling in order to set a recovery order based on which parallel recovery is to be performed for the failed file; and a data management unit for performing parallel recovery for the failed file based on the recovery scheduling.

Here, parallel recovery may include simultaneously recovering multiple files, simultaneously recovering multiple chunk sets of a single file, and performing the two types of parallel recovery at once.

Here, the distributed file system may store a file in units of chunks that are distributed across multiple storage devices using an Erasure Coding (EC) technique.

When the failed file is detected, the metadata management unit may register the failed file in a failed file list, and may perform the recovery scheduling for the failed files in the failed file list.

Here, the metadata management unit may determine whether storage devices to which access is required for recovery of the failed file are available, among the multiple storage devices.

Here, the storage devices to which access is required may include a storage device including a chunk from which data necessary for recovery of the at least one failed file is to be read and a storage device including a chunk to which recovered data is to be written.

Here, the metadata management unit may determine whether the storage devices to which access is required are available depending on whether the storage devices to which access is required are capable of accepting input/output requests. In particular, when determining the capability, the performance requirements of the storage device should be considered.

Here, when it is determined that all of the storage devices to which access is required are available, the metadata management unit may register the failed file in any one of a priority recovery list and a general recovery list depending on whether it is necessary to recover the failed file first.

Here, when it is determined that at least one of the storage devices to which access is required is unavailable, the metadata management unit may register the failed file in the failed file list again.

Here, the data management unit may report a result of performing recovery to the metadata management unit after performing recovery of files registered in the priority recovery list and the general recovery list.

Here, the data management unit may perform parallel recovery by recovering data from chunks in storage devices in which the failed file is stored and by writing the recovered data to storage devices including chunks for writing the recovered data.

Here, the metadata management unit may check the result of parallel recovery performed by the data management unit, analyze the layout of a recovered file, and cancel registration of use of the storage devices that were used to perform parallel recovery.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a block diagram that shows a distributed file system according to an embodiment of the present invention;

FIG. 2 is a view that shows the process of writing data to storage in a distributed file system according to an embodiment of the present invention;

FIG. 3 is a block diagram that shows an apparatus for recovering a distributed file system according to an embodiment of the present invention;

FIG. 4 is a view that shows an erasure-coding process according to an embodiment of the present invention;

FIG. 5 is a view that shows a data storage structure using erasure coding according to an embodiment of the present invention;

FIG. 6 is a view that shows a single disk failure occurring in a data storage structure using 2+2 EC according to an embodiment of the present invention;

FIG. 7 is a view that shows recovery from a single disk failure in a data storage structure using 2+2 EC according to an embodiment of the present invention;

FIG. 8 is a view that shows parallel recovery for a data server failure or multiple-disk failures in a data storage structure using 2+2 EC according to an embodiment of the present invention;

FIG. 9 is a view that shows parallel recovery for a disk failure through recovery scheduling in a distributed file system according to an embodiment of the present invention;

FIG. 10 is a view that shows recovery from two disk failures in a data storage structure using 4+2 EC according to an embodiment of the present invention;

FIG. 11 is a flowchart that shows a method for recovering a distributed file system according to an embodiment of the present invention;

FIG. 12 and FIG. 13 are flowcharts that specifically show an example of the step of performing recovery scheduling illustrated in FIG. 11;

FIG. 14 is a flowchart that specifically shows an example of the step of performing parallel recovery illustrated in FIG. 11;

FIG. 15 is a flowchart that specifically shows an example of the step of performing parallel recovery by a recovery scheduler illustrated in FIG. 14;

FIG. 16 is a flowchart that specifically shows an example of the step of performing a recovery completion process by a recovery worker illustrated in FIG. 14; and

FIG. 17 is a block diagram that shows a computer system according to an embodiment of the present invention.

### DESCRIPTION OF THE PREFERRED EMBODIMENTS

The present invention will be described in detail below with reference to the accompanying drawings. Repeated descriptions and descriptions of known functions and configurations which have been deemed to unnecessarily obscure the gist of the present invention will be omitted below. The embodiments of the present invention are intended to fully describe the present invention to a person having ordinary knowledge in the art to which the present invention pertains. Accordingly, the shapes, sizes, etc. of components in the drawings may be exaggerated in order to make the description clearer.

Throughout this specification, the terms “comprises” and/or “comprising” and “includes” and/or “including” specify the presence of stated elements but do not preclude the presence or addition of one or more other elements unless otherwise specified.

Hereinafter, a preferred embodiment of the present invention will be described in detail with reference to the accompanying drawings.

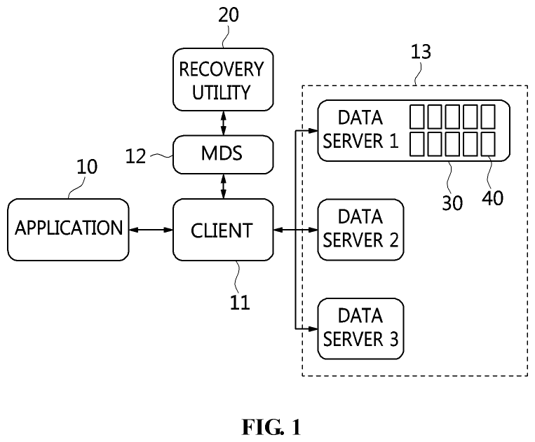

FIG. 1 is a block diagram that shows a distributed file system according to an embodiment of the present invention.

Referring to FIG. 1, the distributed file system according to an embodiment of the present invention may include an application 10, a recovery utility 20, a client 11, a Metadata Server (MDS) 12, and a data server group 13.

Storage may be an apparatus for recovering a distributed file system according to an embodiment of the present invention, and may include the client 11, the metadata server 12, the data server group 13, and the recovery utility 20. The data server group 13 may include multiple data servers (DSs) 30, and each of the data servers 30 may include multiple storage devices 40.

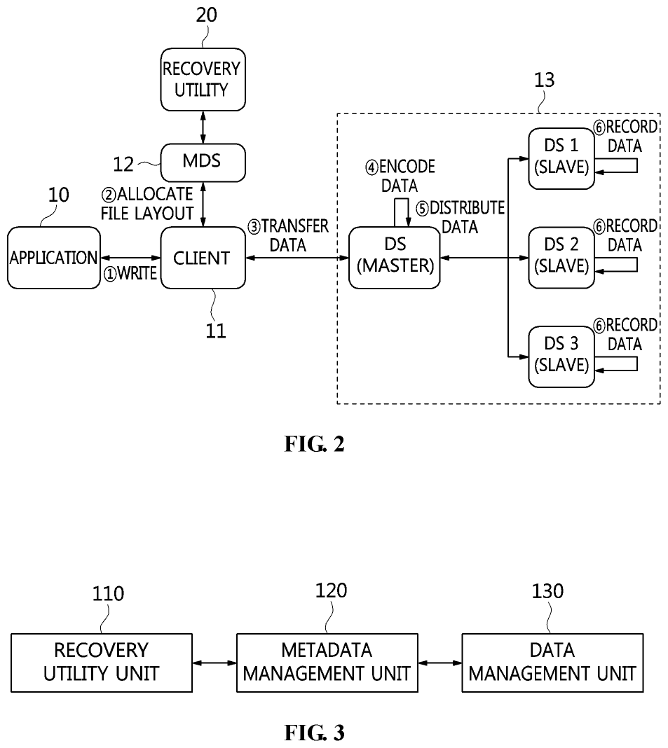

FIG. 2 is a view that shows the process of writing data to storage using erasure coding in a distributed file system according to an embodiment of the present invention.

Referring to FIG. 2, the application 10 may request the client 11 to write a file in the distributed file system.

Here, the client 11 may process a user's request by connecting to the distributed file system.

The client 11 may obtain a file layout from the metadata server 12 in response to the file write request from the application 10.

The file layout may be metadata information about the file, and may include information about a set of chunks that constitute the file.

The metadata server 12 may manage the metadata of a file, and may monitor and manage the distributed file system.

Here, the metadata server 12 may receive the file write request from the client 11 and check whether chunks are allocated.

Here, when it is determined that allocation of chunks is necessary, the metadata server 12 may allocate chunks in the data server group 13, and may deliver a layout, which is information about allocation of the chunks, to the client 11.

The client 11 may analyze the file layout and transmit data to be written to a master data server 30 in the data server group 13.

The data server group 13 may process file input/output requests by receiving the same, and may periodically report the states and load of the data servers to the metadata server 12.

Here, the data servers in the data server group 13 may function as the master data server 30 and slave data servers according to need.

Here, the master data server 30 may be a data server that encodes a file or a chunk set using EC and distributes data for each file. Also, the client 11 may act as the master data server.

Accordingly, for each file, the data server that functions as a master data server 30 may be changed in the data server group 13. Therefore, the client 11 may acquire information about a master data server 30 using information stored in the layout and send a request for I/O processing to the corresponding master data server 30.

The master data server 30 may partition data, encode data, and distribute data across slave data servers.

Here, the master data server 30 may segment original data, perform data encoding in order to calculate parity using erasure code, and distribute data blocks and parity blocks across slave data servers in order to store the same.

Here, a slave data server may receive a block assigned thereto and record the data in a chunk file in the storage device.

The recovery utility 20 may send a request for failure recovery to the metadata server 12 or set or change conditions for recovery according to need.

FIG. 3 is a block diagram that shows an apparatus for recovering a file system according to an embodiment of the present invention.

Referring to FIG. 3, the apparatus for recovering a file system according to an embodiment of the present invention includes a recovery utility unit 110, a metadata management unit 120, and a data management unit 130.

The recovery utility unit 110 may be the recovery utility 20 illustrated in FIG. 1 and FIG. 2.

The metadata management unit 120 may be the metadata server 12 illustrated in FIG. 1 and FIG. 2.

The data management unit 130 may be the data server group 13 illustrated in FIG. 1 and FIG. 2.

Here, the data management unit 130 may include multiple data servers 30, and each of the data servers 30 may include multiple storage devices 40.

Here, using an Erasure Coding (EC) method, a file is broken into multiple pieces of data in units of chunks and distributed across multiple storage devices 40 in the multiple data servers 30.

A request for failure recovery from an administrator is delivered to the metadata management unit 120 through the recovery utility unit 110, whereby the request for failure recovery may be processed.

The metadata management unit 120 may detect a failed file that needs recovery, among files stored in the distributed file system.

Here, the metadata management unit 120 may include units or modules corresponding to a recovery manager, a recovery scheduler, and a recovery worker.

The recovery manager may check files to recover by scanning all of the files, and may register a file in a failed file list when it determines that it is necessary to recover the file.

The recovery scheduler may scan files registered in the failed file list when failure recovery is necessary, and may register a recoverable file in a recovery list.

The recovery worker may comprise multiple recovery workers, and the multiple recovery workers may perform parallel recovery.

Here, when there is a file in the recovery list, the recovery worker may perform preparation work that is necessary in order to request recovery of the file, and may then request the recovery master of the file to recover the file. When there is no file in the recovery list, the recovery worker may request the recovery scheduler to perform recovery scheduling.

Here, the preparation work that is necessary in order to request recovery may be preliminary work for performing recovery, such as deleting a failed chunk, allocating a new chunk for replacing the failed chunk, and the like.

Here, the recovery worker may provide the result of processing performed by the recovery master to the metadata management unit 120.

Here, the metadata management unit 120 may detect a failed file in such a way that the recovery manager scans files stored in the distributed file system in response to a request from the recovery utility unit 110.

Here, the metadata management unit 120 may check the depth and state of data loss by analyzing the failed file.

Here, the metadata management unit 120 may detect a file that needs recovery depending on whether the failed file is recoverable and on preset conditions.

Here, when a failure occurs while the data management unit 130 processes data input/output, the metadata management unit 120 is notified of the failure and requests the recovery manager to perform recovery when it determines that it is necessary to recover the file.

Also, the metadata management unit 120 may perform recovery scheduling using the recovery scheduler.

Here, the metadata management unit 120 may analyze the file that needs recovery and determine whether storage devices to which access is required in order to recover the corresponding file are available.

Here, the metadata management unit 120 may determine whether the storage devices are available depending on whether the storage devices accept input/output requests.

For example, the metadata management unit 120 may check the processing capability of the storage devices, the input/output states thereof, and the like, thereby determining whether the storage devices are available.

For example, when the storage device to which access is required is an SSD that supports multiple channels, the SSD may accept as many read requests as the number of channels thereof. Therefore, when the number of read requests that are being processed is less than the number of channels, the metadata management unit 120 may determine that the storage device is available in response to a new read request.

Here, the storage devices to which access is required may include a storage device including a chunk from which the data required to recover a file is to be read and a storage device including a chunk to which the recovered data is to be written.

Here, when at least one of the storage devices to which access is required is not available, the metadata management unit 120 may register the failed file in the failed file list again.

Also, when all of the storage devices to which access is required are available, the metadata management unit 120 may check whether it is necessary to prioritize the failed file.

Information about whether to prioritize a file when recovery is required may be set when the metadata management unit 120 stores the corresponding file in the storage device.

Here, when it determines that it is necessary to recover the failed file first, the metadata management unit 120 may register the failed file in a priority recovery list, but otherwise, the metadata management unit 120 may register the failed file in a general recovery list.

Also, the recovery worker of the metadata management unit 120 may request recovery scheduling, and may request the data management unit 130 to perform recovery by acquiring information from the priority recovery list or the general recovery list.

Here, the metadata management unit 120 may request the recovery master to perform parallel recovery.

Here, the metadata management unit 120 may again perform recovery scheduling using the recovery scheduler by checking the failed file list.

The data management unit 130 may perform parallel recovery for the failed file based on recovery scheduling.

Here, the data management unit 130 may perform parallel recovery using multiple recovery masters in the data server.

A data server may include a worker. The worker may operate as an I/O master or slave when it performs general input/output, and may also operate as a recovery master or a recovery slave.

That is, a worker may play a different role depending on the request input to the data server. Therefore, workers in a single data server may simultaneously function as an I/O master, a recovery master, an I/O slave, a recovery slave, and the like.

The recovery master may read necessary data in order to reconstruct a failed chunk using at least one recovery slave.

Here, the recovery master may reconstruct chunk data through decoding and record the reconstructed data using at least one recovery slave. The number of recovery slaves that are used may vary depending on EC settings and the number of failures. For example, if failures occur in two chunks when 4+2 EC is used, it is necessary to read four chunks and write two reconstructed chunks, in which case four slaves may read the four chunks, respectively, and two slaves may write the two chunks, respectively.

The recovery slave may read or write chunk data from or to a storage device in response to a request from the recovery master.

Here, the recovery master may be the recovery master that is used to input and output a corresponding chunk set, or parallel recovery may be performed by selecting any one of recovery workers in a certain data server as a recovery manager depending on information about the configuration of the chunk set.

Here, the data management unit 130 may analyze the layout of the chunk set of the failed file.

Here, the data management unit 130 may read data from the chunk of the storage device that is necessary in order to recover the failed file.

Here, the data management unit 130 may decode the data. That is, the data management unit 130 may reconstruct the deleted chunk through erasure coding.

Here, the data management unit 130 may check the chunk of the storage device that is necessary in order to write data.

Here, the data management unit 130 may write data to the chunk.

Here, the data management unit 130 may report completion of recovery to the recovery worker.

Here, the data management unit 130 may report the failure recovery result to the metadata management unit 120.

Also, the metadata management unit 120 may perform a recovery completion process using the recovery worker.

Here, the metadata management unit 120 may check the recovery result.

Here, the metadata management unit 120 may analyze the layout of the recovered file and check whether the use of the storage devices to which access was required is registered.

Here, the metadata management unit 120 may cancel the registration of the use of the storage devices to which access was required.

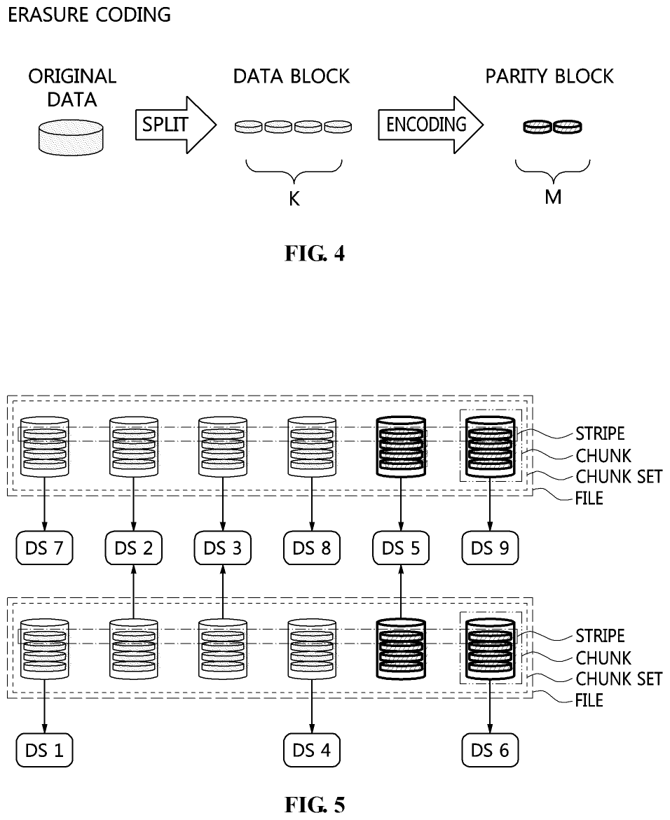

FIG. 4 is a view that shows an erasure-coding process according to an embodiment of the present invention.

Referring to FIG. 4, a data server (DS) according to an embodiment of the present invention may perform erasure coding (EC) on original data. FIG. 4 shows an example in which the size of original data matches the unit for performing encoding, and a description of an example in which the size of the original data is greater or less than the encoding unit is omitted.

As illustrated in FIG. 4, through erasure coding, the original data may be split into K data blocks, and M parity blocks may be generated through encoding.

Here, the erasure code volume may be defined as K+M, in which case K may indicate the number of data blocks into which the original data is split and M may indicate the number of parity blocks generated through encoding (calculation of parity).

FIG. 5 is a view that shows a data storage structure using erasure coding according to an embodiment of the present invention.

Referring to FIG. 5, the data storage structure using erasure coding according to an embodiment of the present invention may be categorized into a file, a chunk set, a chunk, and a stripe.

A stripe is an encoding unit, and may be a set of data blocks and parity blocks related to a single encoding operation.

A chunk is a unit for storing data, and may correspond to a split file stored in each data server (DS).

A chunk set is a set of chunks in which the blocks of a single stripe are stored.

A file may include one or more chunk sets.

That is, a single file may be configured with multiple chunk sets, and data may be written in units of stripes. When the size of a chunk exceeds a preset size, a new chunk set may be allocated.

For example, in 2+2 EC, when the size of a stripe is 256 Kbytes, when the size of a chunk is 640 Kbytes, and when a file of 2560 Kbytes is stored, each stripe takes data of 128 Kbytes, the data is split into two data blocks, and two parity blocks, each of which is 64 Kbytes, may be generated through encoding.

Here, blocks of the same index may be stored in the same chunk, and ten stripes may be collected and stored as a single chunk. That is, ten stripes may be split into two data chunks and two parity chunks and may then be stored, which may be defined as a chunk set. Accordingly, a file of 2560 Kbytes may be stored as two chunk sets, each of which is filled up with data.

Here, in order to ensure availability of a file system, respective chunks included in a single chunk set may be distributed across different data servers if possible.

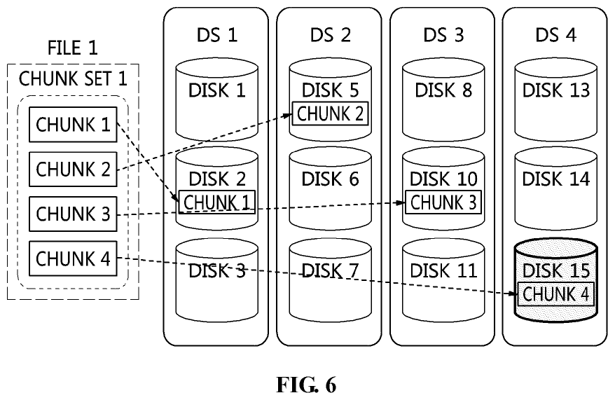

FIG. 6 is a view that shows a single disk failure in a data storage structure using 2+2 EC according to an embodiment of the present invention.

Referring to FIG. 6, in a 2+2 EC volume, file 1, configured with a single chunk set, includes four chunks, which are chunk 1, chunk 2, chunk 3, and chunk 4, and the chunk 1, the chunk 2, the chunk 3, and the chunk 4 are stored in disk 2 in DS 1, disk 5 in DS 2, disk 10 in DS 3, and disk 15 in DS 4, respectively. Here, a failure has occurred in the chunk 4 stored on the disk 15 in the DS 4.

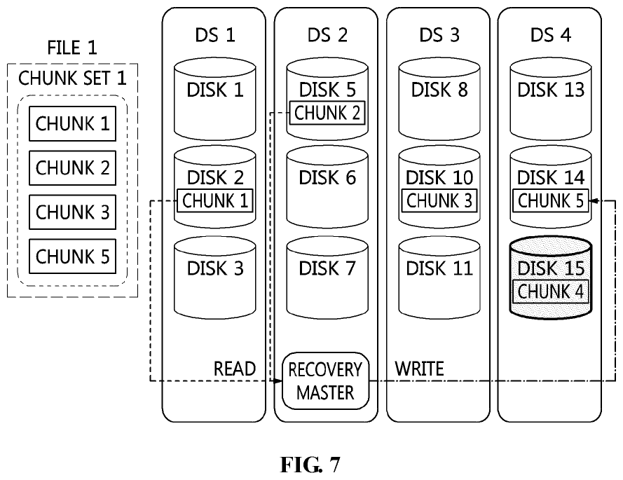

FIG. 7 is a view that shows recovery from a single disk failure in a data storage structure using 2+2 EC according to an embodiment of the present invention.

Referring to FIG. 7, the data of the chunk 4, which is stored on the disk 15, is reconstructed using the recovery master of the DS 2 in the data storage structure shown in FIG. 6.

The recovery master of the DS 2 may read the data of the chunk 1 and the data of the chunk 2 by referring to the configuration of chunks.

Here, the respective DSs may include recovery slaves (not illustrated), and the recovery slave may read each chunk and deliver the same to the recovery master.

Here, after it reconstructs lost data by performing decoding using EC, the recovery master of the DS 2 may write the reconstructed data to chunk 5 in newly allocated disk 14 of the DS 4.

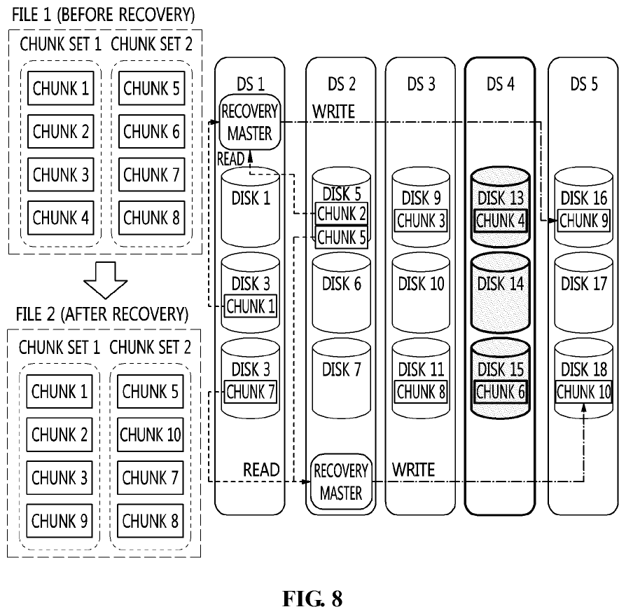

FIG. 8 is a view that shows the result of parallel recovery performed for a data server failure or multiple disk failures in a data storage structure in 2+2 EC according to an embodiment of the present invention.

Referring to FIG. 8, it is confirmed that file 1 in a 2+2 EC volume is stored in DS 1, DS 2, DS 3, DS 4 and DS 5.

Here, the file 1 includes two chunk sets, which are chunk set 1 and chunk set 2.

Here, each of the chunk sets is configured with four chunks depending on the configuration of the 2+2 EC volume. That is, the chunk set 1 includes chunk 1, chunk 2, chunk 3 and chunk 4, and the chunk set 2 includes chunk 5, chunk 6, chunk 7 and chunk 8.

Here, the respective chunks are stored across the DS 1, the DS 2, the DS 3, the DS 4 and the DS 5.

As illustrated in FIG. 8, when a failure occurs in the DS 4, a recovery master in the DS 1 for recovering the chunk set 1 and a recovery master in the DS 2 for recovering the chunk set 2 perform recovery in parallel.

Here, the recovery masters may read data with reference to the configuration of the chunks.

Here, the recovery master in the DS 1 may read the data of the chunk 1 and the data of the chunk 2 from disk 2 and disk 5, respectively.

Here, the recovery master in the DS 1 reconstructs the lost data of the chunk 4 in disk 13 through decoding using EC, and may write the reconstructed data to chunk 9 in newly allocated disk 16.

Also, the recovery master in the DS 2 may read the data of the chunk 7 and the data of the chunk 5 from disk 3 and disk 5, respectively.

Here, the recovery master in the DS2 reconstructs the lost data of the chunk 6 in disk 15 through decoding using EC, and may write the reconstructed data to chunk 10 in newly allocated disk 18.

Accordingly, the data of the chunk 4 and the data of the chunk 6 in the file 1 before recovery are reconstructed and written to the chunk 9 and the chunk 10, respectively, whereby the file 1 is restored to file 2.

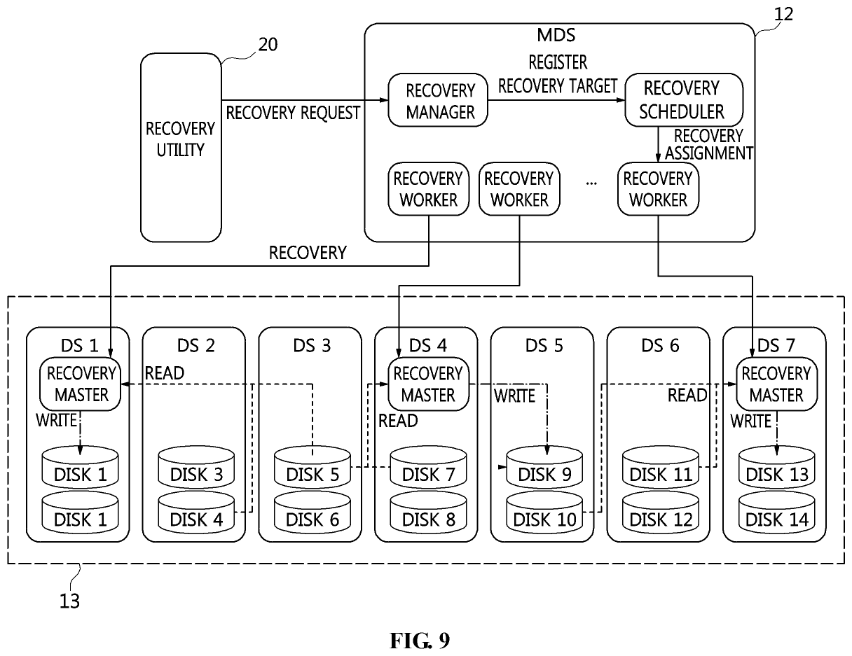

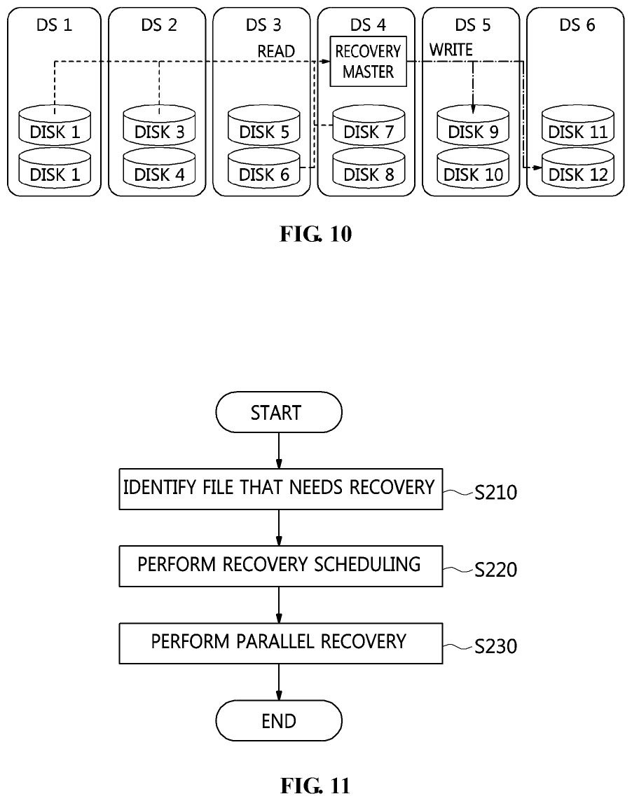

FIG. 9 is a view that shows performing parallel recovery for a disk failure in a distributed file system according to an embodiment of the present invention. FIG. 10 is a view that shows recovery from two disk failures in a data storage structure using 4+2 EC according to an embodiment of the present invention.

Referring to FIG. 9, parallel recovery is performed for disk failures based on recovery scheduling in a distributed file system according to an embodiment of the present invention.

In response to a recovery request from a recovery utility 20, the recovery manager of a metadata server (MDS) 12 may check the file to recover and determine the order of recovery tasks to be performed by recovery workers using a recovery scheduler.

The recovery request is manually made through the recovery utility 20, or the MDS 12 may automatically make a recovery request when a failure, such as a Data Server (DS) failure or the like, is reported thereto.

The recovery manager may check the failure of a file by scanning stored metadata according to need.

The recovery scheduler may allocate recovery workers depending on a recovery order by checking whether a disk to which access is required for recovery of each of multiple files that need recovery is available through recovery scheduling.

Here, the recovery worker may select a recovery master by analyzing a failed file, thereby performing recovery.

The recovery master of a DS may perform data recovery by itself, and may read necessary data from multiple DSs.

Here, after it reconstructs lost data through decoding using EC, the recovery master of the DS may write the reconstructed data to a chunk in a newly allocated disk.

When recovery is finished, the recovery master may return the result of recovery to the recovery worker, and the recovery worker may decide how to process the file depending on the recovery result.

Finally, the recovery worker may report the recovery result to the recovery manager, and may be assigned the next failed file or terminate the recovery process.

The recovery worker may perform recovery by analyzing a failed file, and may perform recovery by selecting a recovery master from a DS group 13 in the event of data loss. Here, parallel recovery using multiple recovery workers may be performed depending on the characteristics of a system and file system software or on the states of resources.

The recovery master may perform data recovery by itself in the DS group 13.

Here, the recovery master may read necessary data from multiple DSs depending on the EC volume configuration pertaining to the data to recover.

For example, referring to FIG. 10, the recovery master of DS 4 accesses six disks in order to recover two pieces of data in 4+2 EC.

Here, the recovery master may reconstruct lost data by decoding the read data using EC, and may write the reconstructed data to a chunk in a newly allocated disk.

Here, when recovery is finished, the recovery master may return the result to the recovery worker, and the recovery worker may decide how to process the file depending on the recovery result.

Finally, the recovery worker may report the recovery result to the recovery manager, and may be assigned the next failed file or terminate the recovery process.

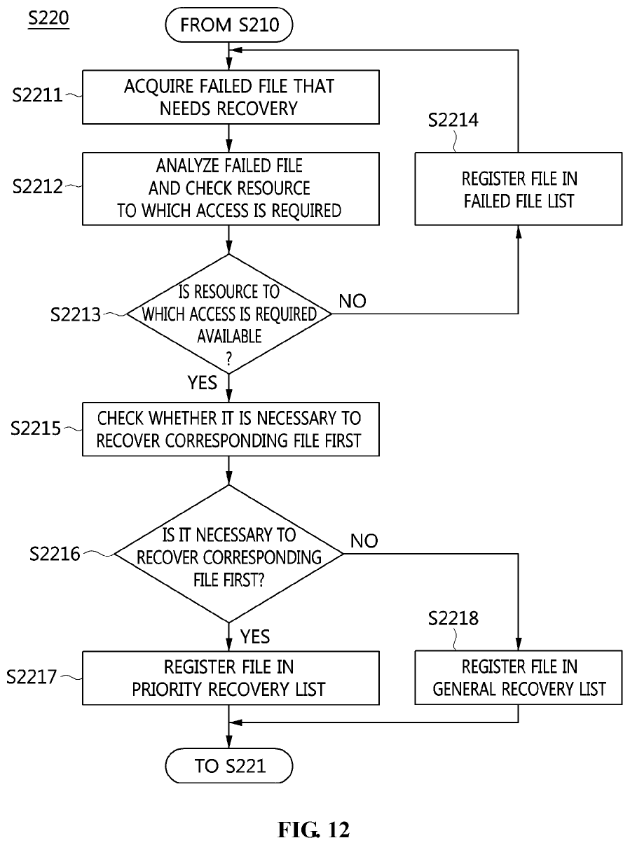

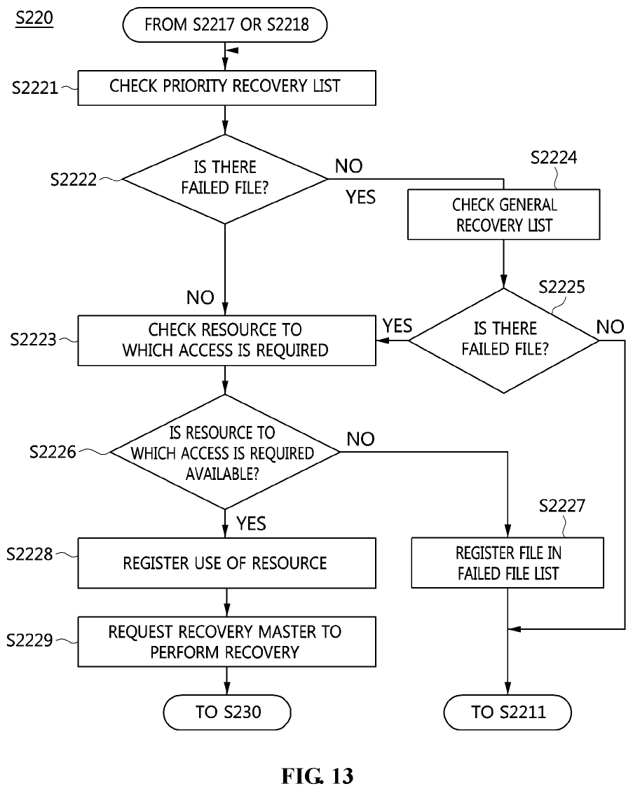

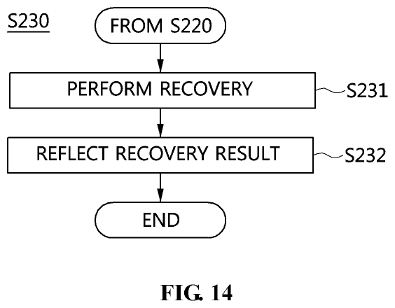

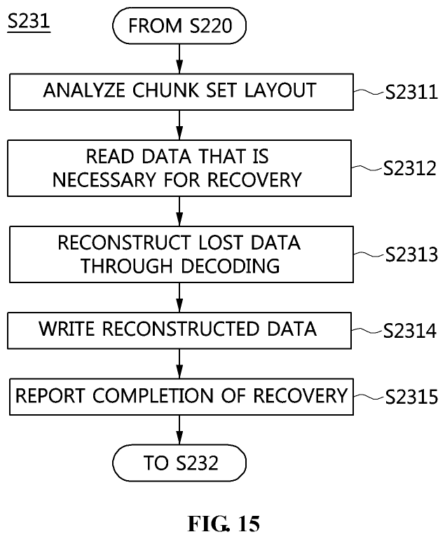

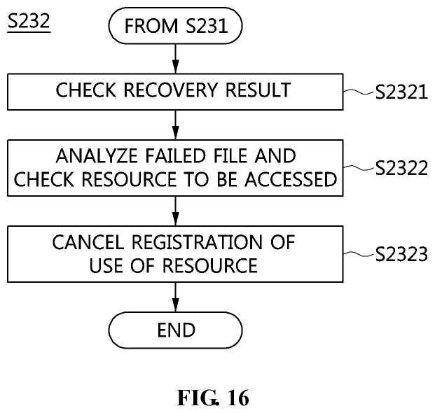

FIG. 11 is a flowchart that shows a method for recovering a distributed file system according to an embodiment of the present invention. FIG. 12 and FIG. 13 are flowcharts that specifically show an example of the step of performing recovery scheduling illustrated in FIG. 11. FIG. 14 is a flowchart that specifically shows an example of the step of performing parallel recovery illustrated in FIG. 11. FIG. 15 is a flowchart that specifically shows the step of performing parallel recovery using a recovery master, illustrated in FIG. 14. FIG. 16 is a flowchart that specifically shows an example of the step of performing a recovery completion process by a recovery worker illustrated in FIG. 14.

Referring to FIG. 11, in the method for recovering a distributed file system according to an embodiment of the present invention, first, a file that needs recovery may be detected at step S210.

Here, at step S210, among files stored in the distributed file system, a failed file that is recoverable and satisfies preset conditions is selected from failed files.

Here, a file may be determined to be recoverable when failures occur in M or fewer chunks, among the chunks of the file, which are distributed across multiple storage devices.

Here, at step S210, the recovery manager inspects all of the files stored in the distributed system through the recovery utility, thereby detecting files that need recovery.

Here, at step S210, when a failure occurs during data input/output, the corresponding file is determined to be a failed file, and a request for recovery may be sent to the recovery manager.

Also, in the method for recovering a distributed file system according to an embodiment of the present invention, recovery scheduling may be performed at step S220.

Referring to FIG. 12, at step S220, a recovery scheduler may perform recovery scheduling.

That is, a file that needs recovery may be acquired at step S2211.

Also, at step S2212, the failed file is analyzed, and whether the storage devices, to which access is required in order to perform parallel recovery for the failed file, are available may be determined.

Here, at step S2212, whether the storage devices to which access is required are available may be determined depending on whether the storage devices may accept input/output requests.

For example, at step S2212, the depth and state of data loss are checked by analyzing the file that needs recovery, and whether the storage devices, to which access is required, are available may be determined depending on the input/output states thereof and the like.

Here, at step S2212, the states may be checked depending on whether the input/output performance of the storage device is degraded.

For example, when the storage device is an SSD that supports multiple channels, if the SSD is capable of accepting a read request because the number of read requests that are being processed is less than the number of channels thereof, the storage device may be determined to be available at step S2212.

Here, the storage devices to which access is required may include a storage device including a chunk from which data necessary for parallel recovery of at least one failed file is to be read and a storage device including a chunk to which the recovered data is to be written.

Here, when it is determined at step S2213 that at least one of the storage devices to which access is required is unavailable, the failed file may be registered as the last entry in the failed file list at step S2214.

Also, when it is determined at step S2213 that all of the storage devices to which access is required are available, whether it is necessary to recover the failed file first may be determined at step S2215.

Information about whether to prioritize a file when recovery is required may be set when the file is created, or may be set depending on the configuration of the volume in which the corresponding file is stored.

Here, when it is determined at step S2216 that it is necessary to recover the file first, the corresponding failed file may be registered in the priority recovery list at step S2217, but otherwise, the failed file may be registered in the general recovery list at step S2218.

Also, at step S220, the recovery worker may request to recover files in the recovery list.

Referring to FIG. 13, the priority recovery list may be checked first at step S2221.

Here, when it is determined at step S2222 that there is a failed file in the priority recovery list, whether the storage devices to which access is required are available may be determined by checking the storage devices at step S2223. When it is determined that there is no file in the priority recovery list, the general recovery list may be checked at step S2224.

Here, when it is determined at step S2225 that there is a failed file in the general recovery list, whether the storage devices to which access is required are available may be determined by checking the storage devices at step S2223. When it is determined that there is no file in the general recovery list, recovery scheduling may be requested again at step S2211.

Here, when it is determined at step S2226 that at least one of the storage devices to which access is required is unavailable, the failed file may be registered as the last entry in the failed file list at step S2227.

Here, at step S2227, recovery scheduling may be performed again by the recovery scheduler using the failed file list by going back to step S2211.

Also, when it is determined at step S2226 that all of the storage devices to which access is required are available, the use of the storage devices may be registered at step S2228.

Here, at step S2229, after recovery preparation work is performed, a request for recovery may be sent to the recovery master. Here, parallel recovery may be performed using multiple recovery masters.

Also, in the method for recovering a distributed file system according to an embodiment of the present invention, parallel recovery may be performed at step S230.

Referring to FIG. 14, parallel recovery may be performed for the failed file based on recovery scheduling at step S231.

That is, at step S231, parallel recovery may be performed using a recovery master included in a data server.

Here, the recovery master may be the recovery master that is used to input and output a corresponding chunk set, or parallel recovery may be performed by selecting any one of recovery workers in a certain data server as a recovery manager depending on information about the configuration of the chunk set.

Referring to FIG. 15, at step S231, the layout of the chunk sets of a failed file may be analyzed at step S2311.

Here, at step S2312, data that is necessary for recovery may be read from the chunk of the storage device that is necessary in order to recover the failed file.

Here at step S2313, lost data may be reconstructed through decoding.

Here, at step S2313, the deleted chunk may be reconstructed through erasure coding.

Here, at step S2313, a chunk of a storage device that is necessary to write data may be checked.

Here, at step S2314, the reconstructed data may be written to the chunk.

Here, at step S2315, the completion of recovery may be reported to the recovery worker.

Here, at step S2315, the recovery result may be reported to the metadata management unit 120.

Also, at step S230, the recovery worker may reflect the recovery result at step S232.

Referring to FIG. 16, at step S232, the recovery result may be checked at step S2321.

Here, at step S2322, the layout of the recovered file is analyzed, and whether the use of storage devices to which access was required is registered may be checked.

Here, at step S2323, the registration of the use of the storage devices, to which access was required, may be canceled. Also, information about changes to the layout depending on the recovery result and the like may be updated.

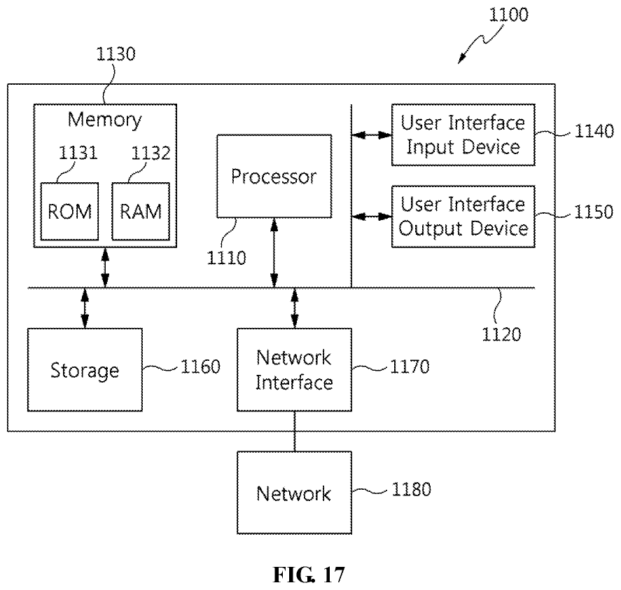

FIG. 17 is a view that shows a computer system according to an embodiment of the present invention

Referring to FIG. 17, the metadata server, the data server, and the apparatus for recovering a distributed file system according to an embodiment of the present invention may be implemented in a computer system 1100 including a computer-readable recording medium. As illustrated in FIG. 17, the computer system 1100 may include one or more processors 1110, memory 1130, a user-interface input device 1140, a user-interface output device 1150, and storage 1160, which communicate with each other via a bus 1120. Also, the computer system 1100 may further include a network interface 1170 connected to a network 1180. The processor 1110 may be a central processing unit or a semiconductor device for executing processing instructions stored in the memory 1130 or the storage 1160. The memory 1130 and the storage 1160 may be various types of volatile or nonvolatile storage media. For example, the memory may include ROM 1131 or RAM 1132.

The present invention may efficiently perform data recovery in a distributed file system in which erasure coding is used.

Also, the present invention minimizes resource contention that is caused when parallel recovery is performed in a distributed file system in which erasure coding is used, whereby a recovery load imposed due to parallel recovery may be efficiently distributed.

Also, the present invention minimizes resource contention in a distributed file system in which erasure coding is used, whereby high-capacity cloud storage having dramatically improved recovery speed may be constructed.

As described above, the apparatus and method for recovering a distributed file system according to the present invention are not limitedly applied to the configurations and operations of the above-described embodiments, but all or some of the embodiments may be selectively combined and configured, so that the embodiments may be modified in various ways.

What is claimed is:

1. A method for recovering a distributed file system, in which an apparatus for recovering a distributed file system is used, comprising:
detecting a failed file that needs recovery, among files stored in a distributed file system;
performing recovery scheduling in order to set a recovery order based on which parallel recovery is to be performed for the failed file; and
performing parallel recovery for the failed file based on the recovery scheduling.

2. The method of claim 1, wherein the failed file is stored in units of chunks that are distributed across multiple storage devices using an Erasure Coding (EC) technique.

3. The method of claim 2, wherein:
detecting the failed file is configured to detect the failed file depending on preset conditions and to register the failed file in a failed file list when the failed file is determined to be recoverable; and
performing the recovery scheduling is configured to perform the recovery scheduling for the failed file in the failed file list.

4. The method of claim 3, wherein performing the recovery scheduling is configured to determine whether storage devices to which access is required for recovery of the failed file are available among the multiple storage devices.

5. The method of claim 4, wherein the storage devices to which access is required include a storage device including a chunk from which data necessary for recovery is to be read and a storage device including a chunk to which recovered data is to be written in order to recover the failed file.

6. The method of claim 5, wherein performing the recovery scheduling is configured to determine whether the storage devices to which access is required are available depending on whether the storage devices to which access is required are capable of accepting input/output requests.

7. The method of claim 6, wherein performing the recovery scheduling is configured such that, when it is determined that all of the storage devices to which access is required are available, the failed file is registered in any one of a priority recovery list and a general recovery list depending on whether it is necessary to recover the failed file first.

8. The method of claim 7, wherein performing the recovery scheduling is configured such that, when it is determined that at least one of the storage devices to which access is required is unavailable, the failed file is again registered in the failed file list.

9. The method of claim 8, wherein performing parallel recovery is configured to perform parallel recovery by recovering data from chunks in storage devices in which the failed file is stored and by writing the recovered data to storage devices including chunks for writing the recovered data.

10. The method of claim 9, wherein performing parallel recovery is configured to check a status of performing parallel recovery, to analyze a layout of a recovered file, and to control registration of use of the storage devices based on the status of performing parallel recovery.

11. An apparatus for recovering a distributed file system, comprising:
a metadata management unit for detecting a failed file that needs recovery, among files stored in a distributed file system, and performing recovery scheduling in order to set a recovery order based on which parallel recovery is to be performed for the failed file; and
a data management unit for performing parallel recovery for the failed file based on the recovery scheduling.

12. The apparatus of claim 11, wherein the failed file is stored in units of chunks that are distributed across multiple storage devices included in the distributed file system using an Erasure Coding (EC) technique.

13. The apparatus of claim 12, wherein the metadata management unit is configured to:
detect the failed file depending on preset conditions and register the failed file in a failed file list when the failed file is determined to be recoverable; and
perform the recovery scheduling for the failed file according to an order of registration in the failed file list.

14. The apparatus of claim 13, wherein the metadata management unit determines whether storage devices to which access is required for recovery of the failed file are available, among the multiple storage devices.

15. The apparatus of claim 14, wherein the storage devices to which access is required include a storage device including a chunk from which data necessary for recovery is to be read and a storage device including a chunk to which recovered data is to be written in order to recover the failed file.

16. The apparatus of claim 15, wherein the metadata management unit determines whether the storage devices to which access is required are available depending on whether the storage devices to which access is required are capable of accepting input/output requests.

17. The apparatus of claim 16, wherein, when it is determined that all of the storage devices to which access is required are available, the metadata management unit registers the failed file in any one of a priority recovery list and a general recovery list depending on whether it is necessary to recover the failed file first.

18. The apparatus of claim 17, wherein, when it is determined that at least one of the storage devices to which access is required is unavailable, the metadata management unit registers the failed file in the failed file list again.

19. The apparatus of claim 18, wherein the data management unit performs parallel recovery by recovering data from chunks in storage devices in which the failed file is stored and by writing the recovered data to storage devices including chunks for writing the recovered data.

20. The apparatus of claim 19, wherein the metadata management unit checks a status of performing parallel recovery, analyzes a layout of a recovered file, and controls registration of use of the storage devices based on the status of performing parallel recovery.
